(19) United States
(12) Patent Application Publication
(10) Pub. No.: US 2026/0324024 A1
(43) Pub. Date: Oct. 15, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventor: Daiki SODA, Tokyo (JP)

(73) Assignee: Mitsubishi Electric Corporation, Tokyo (JP)

(21) Appl. No.: 19/456,251

(22) Filed: Jan. 22, 2026

(30) Foreign Application Priority Data
Apr. 10, 2025 (JP) 2025-064929

(51) Int. Cl. H10D 62/60; H10D 30/01; H10D 30/66; H10D 62/10

(52) U.S. Cl. CPC H10D 62/60; H10D 30/0291; H10D 30/66; H10D 62/124; H10D 62/102

(57) ABSTRACT

A semiconductor device according to the present disclosure includes: a drift layer of a first conductivity type including a first main surface and a second main surface facing the first main surface; a plurality of first impurity regions of a second conductivity type provided on the first main surface side of the drift layer; a JFET region provided between the first impurity regions; a second impurity region of the first conductivity type provided so as to overlap a part of each of the first impurity regions in the JFET region; and a plurality of third impurity regions of the first conductivity type having an impurity concentration peak at a position deeper than an impurity concentration peak of the first impurity region in at least a part of each of the first impurity regions in a depth direction connecting the first main surface and the second main surface.

### BACKGROUND

### Technical Field

The present disclosure relates to a semiconductor device and a method of manufacturing a semiconductor device.

### Description of the Background Art

Silicon carbide (SiC) has attracted attention as a material used for a next-generation power semiconductor device. Hereinafter, a semiconductor device using SiC is also referred to as a SiC semiconductor device. Conventionally, a technique for improving a trade-off between on-resistance and breakdown voltage by providing an n-type doped layer in a junction field effect transistor (JFET) region of a SiC semiconductor device has been disclosed (see, for example, Published Japanese Translation of PCT International Application No. 2021-530878).

In a conventional semiconductor device, an n-type doped layer is provided only in a region centered on a JFET region, and an n-type doped layer is not formed in a region immediately below a p-type well region. Therefore, in the conventional semiconductor device, there has been a problem that the maximum unipolar current at the time of synchronous rectification deteriorates.

### SUMMARY

An object of the present disclosure is to provide a semiconductor device and a method of manufacturing a semiconductor device capable of not only improving the trade-off between on-resistance and breakdown voltage but also improving the maximum unipolar current at the time of synchronous rectification.

A semiconductor device according to the present disclosure includes: a drift layer of a first conductivity type including a first main surface and a second main surface facing the first main surface; a plurality of first impurity regions of a second conductivity type provided on the first main surface side of the drift layer; a junction field effect transistor (JFET) region provided between the first impurity regions; a second impurity region of the first conductivity type provided so as to overlap a part of each of the first impurity regions in the JFET region; and a plurality of third impurity regions of the first conductivity type having an impurity concentration peak at a position deeper than an impurity concentration peak of the first impurity region in at least a part of each of the first impurity regions in a depth direction connecting the first main surface and the second main surface.

According to the present disclosure, not only the trade-off between on-resistance and breakdown voltage can be improved, but also the maximum unipolar current at the time of synchronous rectification can be improved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a semiconductor device according to a first preferred embodiment;

FIG. 2 is a cross-sectional view schematically illustrating a configuration of the semiconductor device according to the first preferred embodiment;

FIG. 3 is a graph illustrating a relationship between a drain current and a drain-source voltage (on-voltage) when a photomask forming a first NW region and a photomask forming a well region do not overlap each other;

FIG. 4 is a graph illustrating a relationship between a drain current and a drain-source voltage (on-voltage) when a photomask forming the first NW region and a photomask forming a well region overlap each other;

FIG. 5 is a graph illustrating a relationship between a source current and a source-drain voltage at the time of synchronous rectification in each of a case of only the first NW region and a case of the first NW region and a second NW region;

FIG. 6 is a cross-sectional view schematically illustrating a configuration of a semiconductor device according to a second preferred embodiment;

FIG. 7 is a cross-sectional view schematically illustrating a configuration of a semiconductor device according to a third preferred embodiment;

FIG. 8 is a graph illustrating a relationship between a source current and a source-drain voltage at the time of synchronous rectification when a photomask forming a first NW region and a photomask forming a second NW region overlap each other and when the photomasks do not overlap each other;

FIG. 9 is a cross-sectional view schematically illustrating a configuration of a semiconductor device according to a fourth preferred embodiment;

FIG. 10 is a cross-sectional view schematically illustrating a configuration of a semiconductor device according to a fifth preferred embodiment;

FIG. 11 is a cross-sectional view schematically illustrating a configuration of a semiconductor device according to a sixth preferred embodiment;

FIG. 12 is a cross-sectional view schematically illustrating a configuration of a semiconductor device according to a seventh preferred embodiment;

FIG. 13 is a cross-sectional view schematically illustrating a configuration of a semiconductor device according to an eighth preferred embodiment;

FIG. 14 is a cross-sectional view schematically illustrating a configuration of a semiconductor device according to a ninth preferred embodiment;

FIG. 15 is a cross-sectional view schematically illustrating a configuration of a semiconductor device according to a tenth preferred embodiment;

FIG. 16 is a plan view schematically illustrating a cell structure constituting a semiconductor device according to an eleventh preferred embodiment;

FIG. 17 is a plan view schematically illustrating a cell structure constituting a semiconductor device according to a twelfth preferred embodiment;

FIG. 18 is a cross-sectional view schematically illustrating a configuration of a semiconductor device according to a thirteenth preferred embodiment;

FIG. 19 is a flowchart illustrating a manufacturing process of a semiconductor device according to a fourteenth preferred embodiment;

FIG. 20 is a flowchart illustrating a manufacturing process of a semiconductor device according to a fifteenth preferred embodiment;

FIG. 21 is a flowchart illustrating a manufacturing process of a semiconductor device according to a sixteenth preferred embodiment; and

FIG. 22 is a flowchart illustrating a manufacturing process of a semiconductor device according to a seventeenth preferred embodiment.

### DESCRIPTION OF THE PREFERRED EMBODIMENTS

In the following description, n and p represent the conductivity type of a semiconductor. In the present disclosure, a first conductivity type is n-type and a second conductivity type is p-type, but the first conductivity type may be p-type and the second conductivity type may be n-type.

Hereinafter, preferred embodiments will be described with reference to the accompanying drawings. Note that the drawings are schematically illustrated, and the mutual relationship between the sizes and positions of images illustrated in different drawings is not necessarily accurately described, and can be appropriately changed. Furthermore, in the following description, similar components are denoted by the same reference signs and have similar names and functions. Therefore, detailed description thereof may be omitted.

In addition, in the following description, terms meaning specific positions and directions such as “upper”, “lower”, “side”, “bottom”, “front”, and “back” may be used, but these terms are used for convenience to facilitate understanding of the contents of the preferred embodiments and are not related to directions when actually implemented.

### First Preferred Embodiment

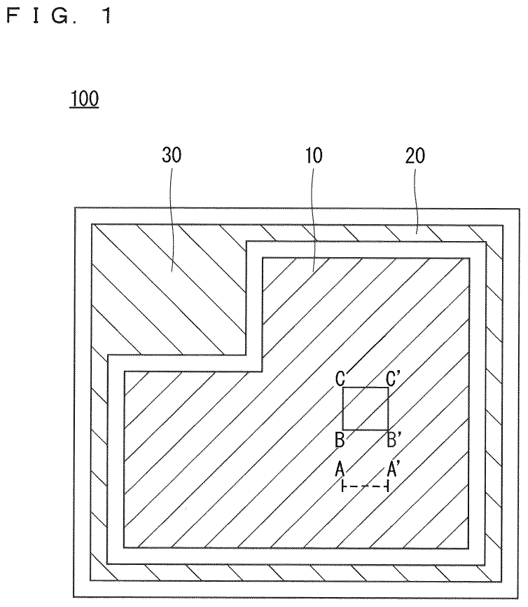

FIG. 1 is a plan view of a configuration of a semiconductor device 100 according to a first preferred embodiment as viewed from above. The semiconductor device 100 is a SiC metal oxide semiconductor field effect transistor (MOSFET).

As illustrated in FIG. 1, a gate pad 30 is provided on a part (upper left in FIG. 1) of an upper surface of the semiconductor device 100, and a source electrode 10 is provided adjacent to the gate pad 30. Gate wiring 20 extends from the gate pad 30 and is provided so as to surround the source electrode 10. The source electrode 10 is electrically insulated from the gate wiring 20 and the gate pad 30.

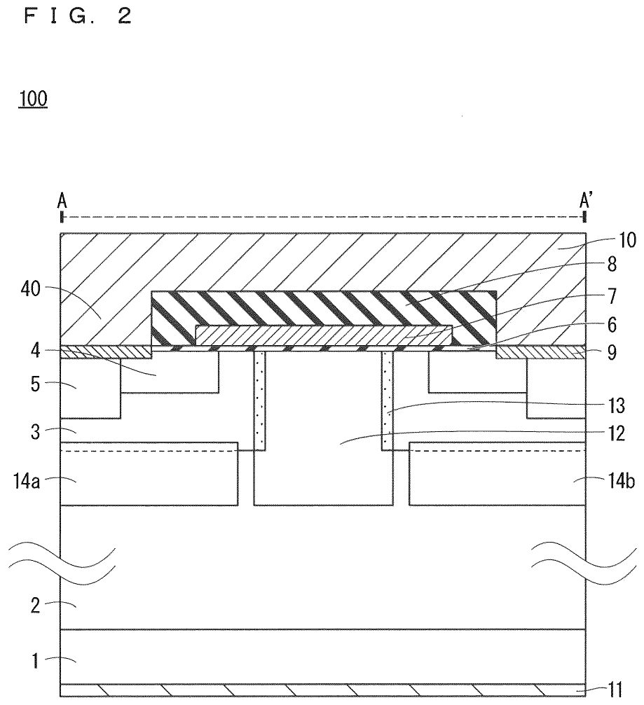

FIG. 2 is a cross-sectional view schematically illustrating a cell structure of the semiconductor device 100 according to the first preferred embodiment. Specifically, the semiconductor device 100 illustrated in FIG. 2 is a cross-sectional view taken along line A-A′ illustrated in FIG. 1.

As illustrated in FIG. 2, in semiconductor device 100, a drift layer 2 made of n-type silicon carbide is provided on a semiconductor substrate 1 made of n-type low-resistance silicon carbide. The drift layer 2 has a first main surface which is an upper surface in the drawing and a second main surface which is a lower surface in the drawing. The first main surface and the second main surface face each other. The n-type impurity concentration of the drift layer 2 is 1×10¹⁵ cm⁻³ to 1×10¹⁷ cm⁻³. A film thickness of the drift layer 2 is desirably 5 μm to 50 μm.

A well region 3 (first impurity region) made of p-type silicon carbide is provided in a surface layer portion of the drift layer 2. The well regions 3 may be connected to each other or a plurality of the well regions 3 may be provided separately. In the example of FIG. 2, a plurality of well regions 3 are provided. Hereinafter, a region between the well regions 3 is referred to as a junction transistor region (JFET region). The p-type impurity concentration of the well region 3 is 1×10¹⁷ cm⁻³ to 1×10¹⁹ cm⁻³. The ion implantation depth of the well region 3 is 0.4 μm to 3 μm, and is desirably thinner than the film thickness of the drift layer 2.

In a surface layer portion of each well region 3, a source region 4 (fourth impurity region) made of n-type silicon carbide is provided at a position inside by a predetermined interval from the outside of the well region 3 (side opposite to JFET region of well region 3). The n-type impurity concentration of the source region 4 is 1×10¹⁸ cm⁻³ to 1×10²¹ cm⁻³. The source region 4 is thinner than the well region 3.

A well contact region 5 (fifth impurity region) made of low-resistance p-type silicon carbide is provided outside the source region 4 in each well region 3. The p-type impurity concentration of the well contact region 5 is higher than the p-type impurity concentration of the well region 3, and is desirably formed by high-temperature implantation at 150 °C or higher.

An ohmic electrode 9 is provided on the surfaces (on first main surface) of the source region 4 and the well contact region 5. The source electrode 10 connected to the ohmic electrode 9 is provided on the ohmic electrode 9. The well region 3 can easily exchange electrons and holes with the ohmic electrode 9 via the well contact region 5 having low resistance.

A gate insulating film 6 made of silicon oxide is provided on the surface of the source region 4 in the adjacent well region 3. A gate electrode 7 made of polycrystalline silicon is provided on the gate insulating film 6 and at least above the well region 3. An interlayer insulating film 8 made of silicon oxide is provided between the gate electrode 7 and the source electrode 10. A region that is a surface layer portion of the well region 3 and faces the gate electrode 7 via the gate insulating film 6 is referred to as a channel region.

A contact region 40 is provided to penetrate the interlayer insulating film 8. The contact region 40 is also referred to as a contact hole. The ohmic electrode 9 and the source electrode 10 above the well contact region 5 are connected to the source electrode 10 on the interlayer insulating film 8 via the contact region 40.

A drain electrode 11 is provided on the back surface side (second main surface side) of the semiconductor substrate 1.

In the semiconductor device 100, an n-type first NW region 12 (second impurity region) is provided in the JFET region. The first NW region 12 partially overlaps the well region 3, and this overlapping portion is referred to as an overlapping region 13. The overlapping region 13 is not formed over the entire well region 3, but may overlap the source region 4 and the well contact region 5. The n-type impurity layer of the first NW region 12 is formed deeper than the p-type impurity layer of the well region 3. The n-type impurity concentration of the first NW region 12 desirably has a profile that attenuates from a deep portion to a shallow portion.

In at least a part of the lower part of the well region 3, n-type second NW regions 14a and 14b (third impurity regions) are provided. The n-type impurity concentration peaks of the second NW regions 14a and 14b are located at positions deeper than the p-type impurity concentration peak of the well region 3.

The impurity concentration of the first NW region 12 and the impurity concentration of the second NW regions 14a and 14b may be the same or may be different. The impurity concentration of each of first NW region 12 and second NW regions 14a and 14b is higher than that of the drift layer 2, and is a concentration that is depleted at the maximum rated voltage.

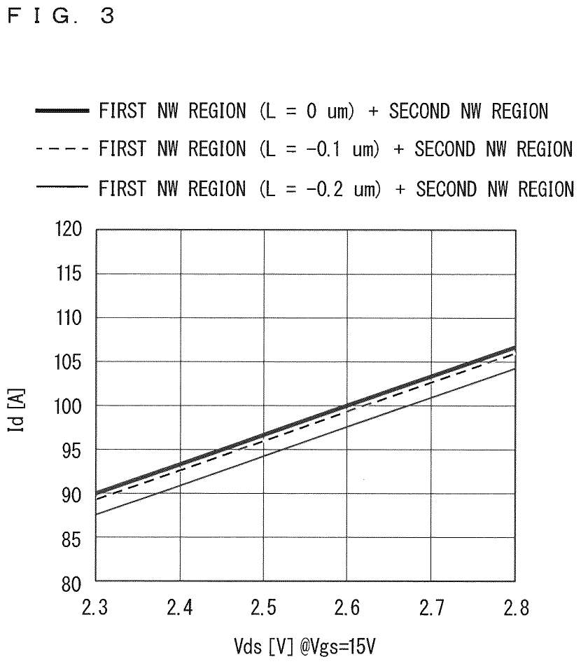

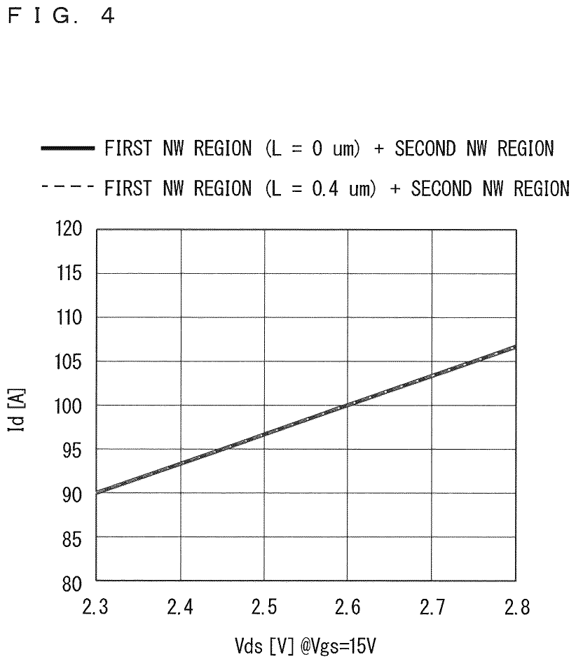

For example, in the conventional semiconductor device as in Published Japanese Translation of PCT International Application No. 2021-530878, since the first NW region 12 and the well region 3 do not overlap as in the present first preferred embodiment, variations in threshold voltage and on-voltage due to deviation in mask superposition at the time of mass production increase (see FIG. 3). Note that in FIG. 3, L corresponds to the overlapping length of the photomask (length of overlapping region 13) used for forming each of the first NW region 12 and the well region 3. When L is negative, it indicates that the photomasks do not overlap each other, and when L is positive, it indicates that the photomasks overlap each other. The same applies to FIGS. 4, 5, and 8 described later.

In addition, in the conventional semiconductor device, since the second NW regions 14a and 14b are not provided as in the present first preferred embodiment, the energy barrier of the PN junction between the well region 3 and the drift layer 2 is small, and the bipolar operation is started at a low voltage, so that the maximum unipolar current at the time of synchronous rectification may be deteriorated.

In the semiconductor device according to the present first preferred embodiment, since the first NW region 12 is not formed in the entire well region 3, the first NW region 12 overlapping the well region 3 is small, and the impurity concentration peaks of the second NW regions 14a and 14b are at positions deeper than the impurity concentration peak of the well region 3, so that the charge of the n-type concentration present in the well region 3 is reduced. Therefore, the sheet resistance of the well region 3 can be reduced, the rise of the voltage of the well region 3 can be suppressed, and the deterioration of loss due to malfunction can be suppressed.

Furthermore, in the semiconductor device according to the present first preferred embodiment, since the first NW region 12 is provided, it is possible to reduce variations in threshold voltage and on-voltage due to deviation in photomask superposition at the time of mass production (see FIG. 4).

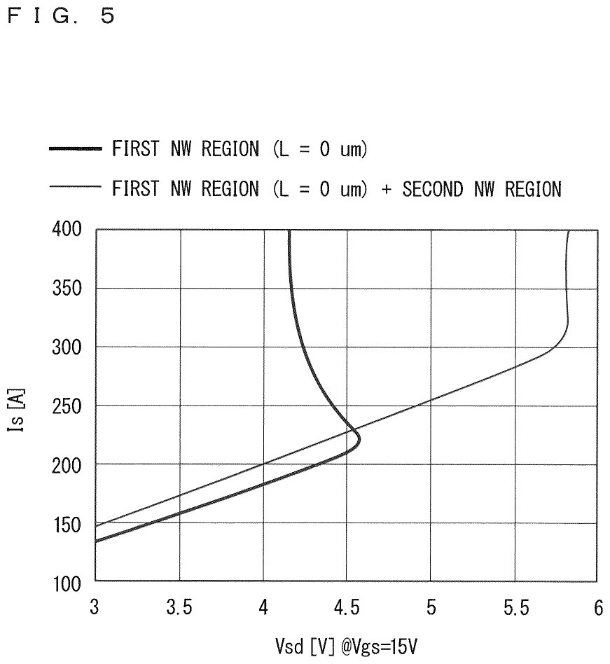

Furthermore, in the semiconductor device according to the present first preferred embodiment, since the second NW regions 14a and 14b having an n-type impurity concentration higher than that of the drift layer 2 are provided, the energy barrier of the PN junction between the well region 3 and the drift layer 2 becomes large, and the bipolar operation becomes difficult to perform. Therefore, the maximum unipolar current at the time of synchronous rectification, which is the inflection point of the waveform showing the relationship between the source current and the source-drain voltage illustrated in FIG. 5, can be improved.

As described above, the semiconductor device according to the present first preferred embodiment can reduce variations in threshold voltage and on-voltage during mass production while suppressing deterioration of loss due to malfunction, as compared with the conventional semiconductor device. In addition, since the maximum unipolar current at the time of synchronous rectification can be improved, even if driving is performed at a high current density at the time of synchronous rectification, the risk of expansion of the stacking fault can be suppressed, and the reliability of the semiconductor device can be improved.

### Second Preferred Embodiment

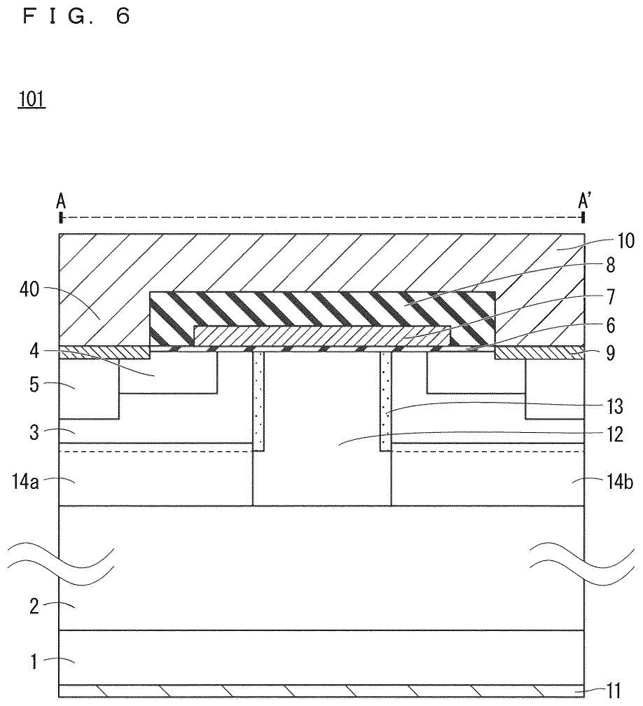

FIG. 6 is a cross-sectional view schematically illustrating a cell structure of a semiconductor device 101 according to a second preferred embodiment. The semiconductor device 101 according to the second preferred embodiment is another form of the semiconductor device 100 (see FIG. 2) according to the first preferred embodiment.

As illustrated in FIG. 6, in the semiconductor device 101, a first NW region 12 provided with a JFET region at the center of the first NW region 12 is connected to second NW regions 14a and 14b provided below a well region 3.

Here, the connection between the first NW region 12 and the second NW regions 14a and 14b specifically means that the n-type impurity concentration peaks of the second NW regions 14a and 14b are the same as the impurity concentration of the first NW region 12 at the same depth as the second NW regions 14a and 14b.

The semiconductor device 101 has an overlapping region 13 in which the first NW region 12 and the well region 3 overlap, similarly to the semiconductor device 100 according to the first preferred embodiment. The overlapping region 13 is not provided in the entire well region 3, but may overlap a source region 4 and a well contact region 5.

In the semiconductor device 101 according to the second preferred embodiment, since the first NW region 12 and the second NW regions 14a and 14b are connected, the maximum unipolar current at the time of synchronous rectification can be improved as compared with the semiconductor device 100 according to the first preferred embodiment.

### Third Preferred Embodiment

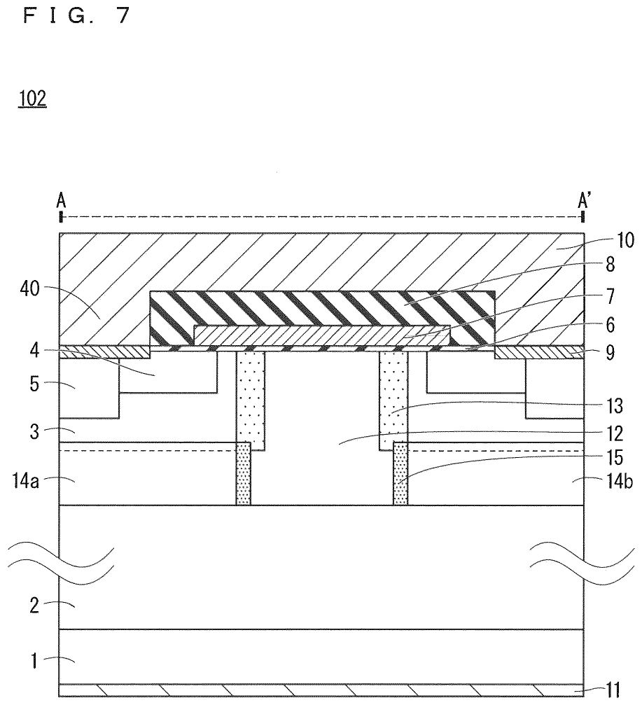

FIG. 7 is a cross-sectional view schematically illustrating a cell structure of a semiconductor device 102 according to a third preferred embodiment. The semiconductor device 102 according to the third preferred embodiment is another form of the semiconductor device 101 (see FIG. 6) according to the second preferred embodiment.

As illustrated in FIG. 7, in the semiconductor device 102, a first NW region 12 provided with a JFET region at the center of the first NW region 12 and second NW regions 14a and 14b provided in lower parts of a well region 3 overlap each other.

Here, the overlapping of the first NW region 12 and the second NW regions 14a and 14b specifically means that the n-type impurity concentration of an overlapping region 15 where the first NW region 12 and the second NW regions 14a and 14b overlap is higher than the n-type impurity concentration of each of the first NW region 12 and the second NW regions 14a and 14b. The overlapping region 15 is not provided in the entire well region 3, but may overlap a source region 4 and a well contact region 5.

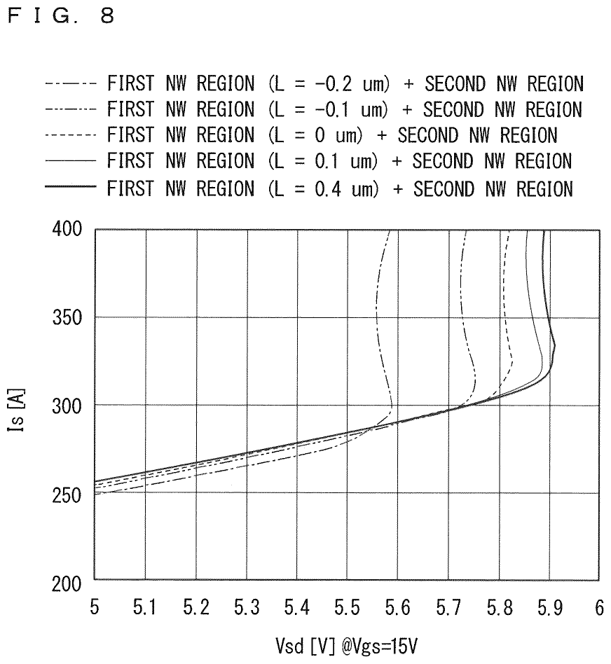

In the semiconductor device 102 according to the third preferred embodiment, since the first NW region 12 and the second NW regions 14a and 14b overlap each other, as illustrated in FIG. 8, it is possible to reduce the variation in the maximum unipolar current at the time of synchronous rectification due to deviation in photomask superposition at the time of mass production as compared with the semiconductor device 101 according to the second preferred embodiment.

### Fourth Preferred Embodiment

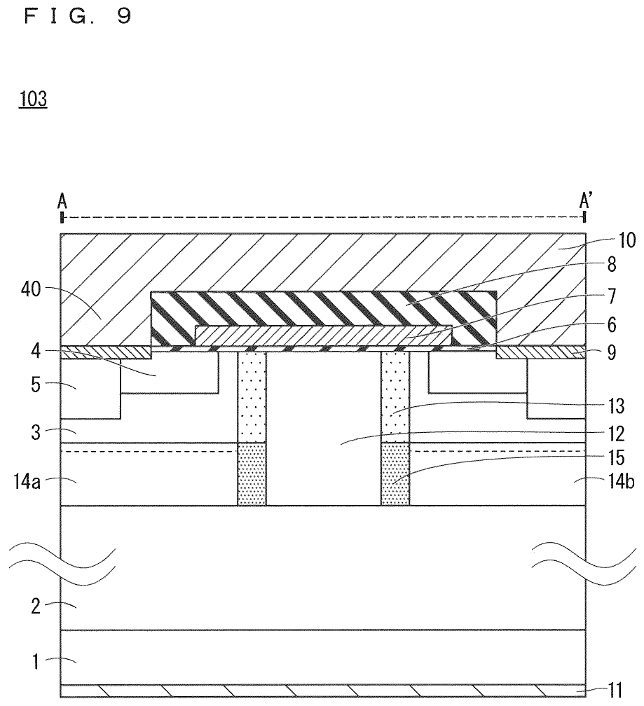

FIG. 9 is a cross-sectional view schematically illustrating a cell structure of a semiconductor device 103 according to a fourth preferred embodiment. The semiconductor device 103 according to the fourth preferred embodiment is another form of the semiconductor device 102 (see FIG. 7) according to the third preferred embodiment.

As illustrated in FIG. 9, in the semiconductor device 103, a well region 3 and second NW regions 14a and 14b provided below the well region 3 have substantially the same dimensions. Specifically, in the horizontal direction that is orthogonal to the depth direction (direction connecting first main surface and second main surface), the dimension of the well region 3 is substantially the same as the dimensions of the second NW regions 14a and 14b. Here, “substantially the same” means exactly the same or including some errors.

Here, the fact that well region 3 and the second NW regions 14a and 14b have substantially the same dimension means that an overlapping region 13 of a well region 3 and a first NW region 12 has substantially the same dimension as an overlapping region 15 of the first NW region 12 and the second NW regions 14a and 14b. The overlapping region 13 having substantially the same dimension as the overlapping region 15 is not provided in the entire well region 3, but may overlap a source region 4 and a well contact region 5.

In the semiconductor device 103 according to the fourth preferred embodiment, since the well region 3 and the second NW regions 14a and 14b have substantially the same dimensions, it is possible to form the regions with the same photomask as compared with the semiconductor device 102 according to the third preferred embodiment, so that the manufacturing cost of the semiconductor device can be reduced.

### Fifth Preferred Embodiment

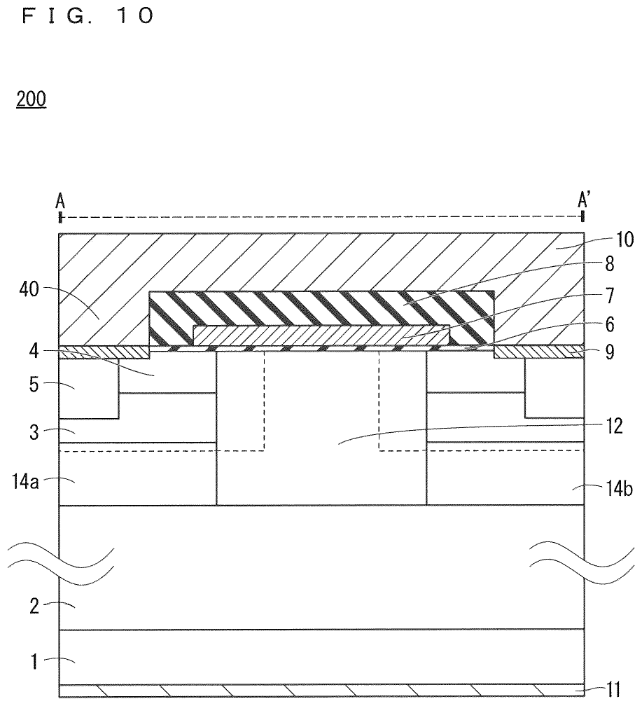

FIG. 10 is a cross-sectional view schematically illustrating a cell structure of a semiconductor device 200 according to a fifth preferred embodiment. The semiconductor device 200 according to the fifth preferred embodiment is another form of the semiconductor device 103 (see FIG. 9) according to the fourth preferred embodiment.

As illustrated in FIG. 10, in the semiconductor device 200, a first NW region 12 is provided in a JFET region and a channel region. In addition, second NW regions 14a and 14b provided below a well region 3 have substantially the same dimensions as the sum of a source region 4 and a well contact region 5. Specifically, in the horizontal direction orthogonal to the depth direction (direction connecting first main surface and second main surface), the dimensions of the second NW regions 14a and 14b are substantially the same as the sum of the dimension of the source region 4 and the dimension of the well contact region 5. Note that in the example of FIG. 10, a structure in which the source region 4 and the well contact region 5 are arranged so as to be orthogonal to each other is illustrated, but a structure in which the source region 4 and the well contact region 5 are alternately arranged may also be considered. In such a structure, for example, since there is no well contact region 5 in FIG. 10, the dimensions of the second NW regions 14a and 14b are substantially the same as the dimension of the source region 4.

The first NW region 12 and the second NW regions 14a and 14b are connected to each other. Therefore, the first NW region 12 is also connected to the source region 4.

Here, the connection between the first NW region 12 and the second NW regions 14a and 14b specifically means that the n-type impurity concentration peaks of the second NW regions 14a and 14b are the same as the impurity concentration of the first NW region 12 at the same depth as the second NW regions 14a and 14b.

In the semiconductor device 200 according to the fifth preferred embodiment, since the first NW region 12 and the second NW regions 14a and 14b are connected, the maximum unipolar current at the time of synchronous rectification can be improved as compared with the semiconductor device 100 according to the first preferred embodiment. In addition, since the second NW regions 14a and 14b have substantially the same dimensions as the sum of the source region 4 and the well contact region 5, it is possible to manufacture the second NW regions with the same photomask as the photomask used for forming the source region 4, and it is possible to reduce the manufacturing cost of the semiconductor device.

### Sixth Preferred Embodiment

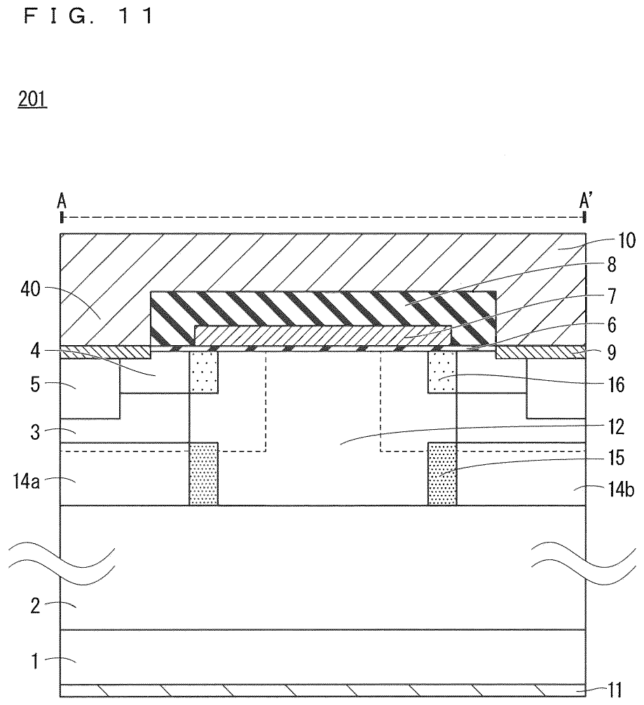

FIG. 11 is a cross-sectional view schematically illustrating a cell structure of a semiconductor device 201 according to a sixth preferred embodiment. The semiconductor device 201 according to the sixth preferred embodiment is another form of the semiconductor device 200 (see FIG. 10) according to the fifth preferred embodiment.

As illustrated in FIG. 11, in the semiconductor device 201, a first NW region 12 is provided with a JFET region and a channel region at the center of the first NW region 12. In addition, second NW regions 14a and 14b provided below a well region 3 have substantially the same dimensions as the sum of a source region 4 and a well contact region 5. Specifically, in the horizontal direction orthogonal to the depth direction (direction connecting first main surface and second main surface), the dimensions of the second NW regions 14a and 14b are substantially the same as the sum of the dimension of the source region 4 and the dimension of the well contact region 5. Note that in the example of FIG. 11, a structure in which the source region 4 and the well contact region 5 are arranged so as to be orthogonal to each other is illustrated, but a structure in which the source region 4 and the well contact region 5 are alternately arranged may also be considered. In such a structure, for example, since there is no well contact region 5 in FIG. 11, the dimensions of the second NW regions 14a and 14b are substantially the same as the dimension of the source region 4.

The first NW region 12 and the second NW regions 14a and 14b overlap. Therefore, the first NW region 12 also overlaps the source region 4.

Here, the overlapping of the first NW region 12 and the second NW regions 14a and 14b specifically means that the n-type impurity concentration of an overlapping region 15 where the first NW region 12 and the second NW regions 14a and 14b overlap is higher than the n-type impurity concentration of each of the first NW region 12 and the second NW regions 14a and 14b. An overlapping region 16 of the source region 4 and the first NW region 12 has substantially the same dimension as the overlapping region 15 of the first NW region 12 and the second NW regions 14a and 14b. The overlapping region 16 is not provided in the entire well region 3 centered on the source region 4, but may overlap the well contact region 5.

In the semiconductor device 201 according to the sixth preferred embodiment, since the first NW region 12 and the source region 4 overlap each other, as compared with the semiconductor device 200 according to the fifth preferred embodiment, it is possible to reduce variations in threshold voltage and on-voltage due to deviation in photomask superposition at the time of mass production. In addition, since the first NW region 12 and the second NW regions 14a and 14b overlap each other, it is possible to reduce variation in the maximum unipolar current at the time of synchronous rectification due to deviation in photomask superposition at the time of mass production.

### Seventh Preferred Embodiment

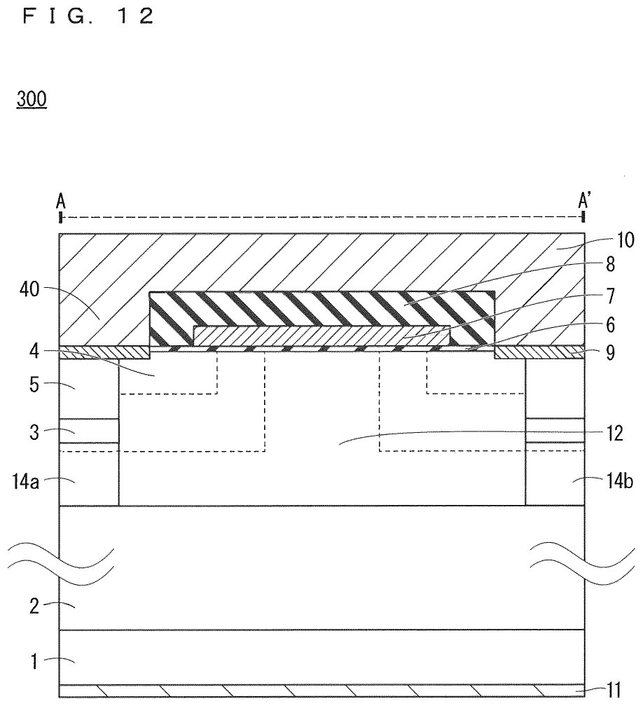

FIG. 12 is a cross-sectional view schematically illustrating a cell structure of a semiconductor device 300 according to a seventh preferred embodiment. The semiconductor device 300 according to the seventh preferred embodiment is another form of the semiconductor device 200 (see FIG. 10) according to the fifth preferred embodiment.

As illustrated in FIG. 12, in the semiconductor device 300, a first NW region 12 is provided in a JFET region, a channel region, and a source region 4. Moreover, second NW regions 14a and 14b provided below a well region 3 have substantially the same dimension as the well contact region 5. Specifically, in the horizontal direction orthogonal to the depth direction (direction connecting first main surface and second main surface), the dimensions of the second NW regions 14a and 14b are substantially the same as the dimension of the well contact region 5.

The first NW region 12 and the second NW regions 14a and 14b are connected to each other. Therefore, the first NW region 12 is also connected to the well contact region 5.

Here, the connection between the first NW region 12 and the second NW regions 14a and 14b specifically means that the n-type impurity concentration peaks of the second NW regions 14a and 14b are substantially the same as the impurity concentration of the first NW region 12 at the same depth as the second NW regions 14a and 14b.

In the semiconductor device 300 according to the seventh preferred embodiment, since the first NW region 12 and the second NW regions 14a and 14b are connected, the maximum unipolar current at the time of synchronous rectification can be improved as compared with the semiconductor device 100 according to the first preferred embodiment. In addition, since the second NW regions 14a and 14b have substantially the same dimensions as the well contact region 5, it is possible to manufacture the second NW regions 14a and 14b with the same photomask as the photomask used for forming the well contact region 5, and it is possible to reduce the manufacturing cost of the semiconductor device.

### Eighth Preferred Embodiment

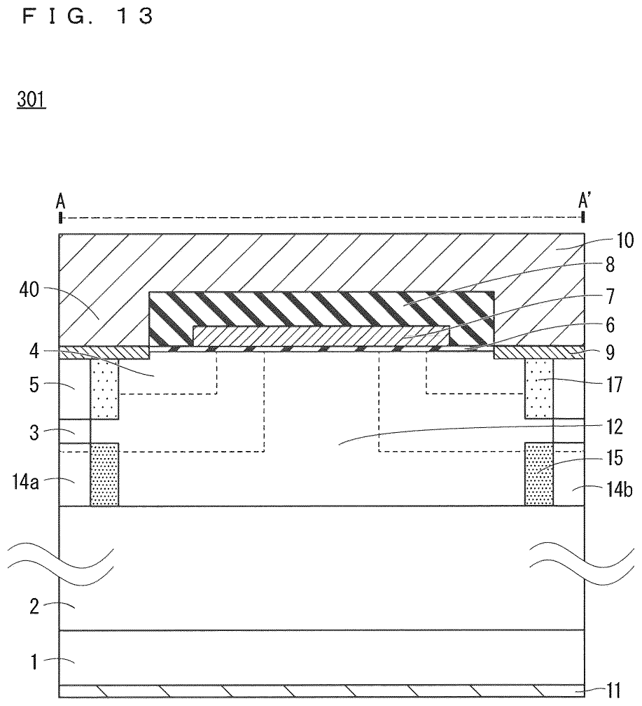

FIG. 13 is a cross-sectional view schematically illustrating a cell structure of a semiconductor device 301 according to an eighth preferred embodiment. The semiconductor device 301 according to the eighth preferred embodiment is another form of the semiconductor device 300 (see FIG. 12) according to the seventh preferred embodiment.

As illustrated in FIG. 13, in the semiconductor device 301, a first NW region 12 is provided in a part of a JFET region, a channel region, a source region 4, and a well contact region 5. Moreover, second NW regions 14a and 14b provided below a well region 3 have substantially the same dimension as the well contact region 5. Specifically, in the horizontal direction orthogonal to the depth direction (direction connecting first main surface and second main surface), the dimensions of the second NW regions 14a and 14b are substantially the same as the dimension of the well contact region 5.

The first NW region 12 and the second NW regions 14a and 14b overlap. Therefore, the first NW region 12 also overlaps the well contact region 5.

Here, the overlapping of the first NW region 12 and the second NW regions 14a and 14b specifically means that the n-type impurity concentration of an overlapping region 15 where the first NW region 12 and the second NW regions 14a and 14b overlap is higher than the n-type impurity concentration of each of the first NW region 12 and the second NW regions 14a and 14b. The overlapping of the first NW region 12 and the second NW regions 14a and 14b also means that an overlapping region 17 of the well contact region 5 and the first NW region 12 has substantially the same dimension as the overlapping region 15 of the first NW region 12 and the second NW regions 14a and 14b. The overlapping region 17 is not provided in the entire well region 3 centered on the well contact region 5.

In the semiconductor device 301 according to the eighth preferred embodiment, since the first NW region 12 and the second NW regions 14a and 14b overlap each other, it is possible to reduce variation in maximum unipolar current at the time of synchronous rectification due to deviation in photomask superposition at the time of mass production.

### Ninth Preferred Embodiment

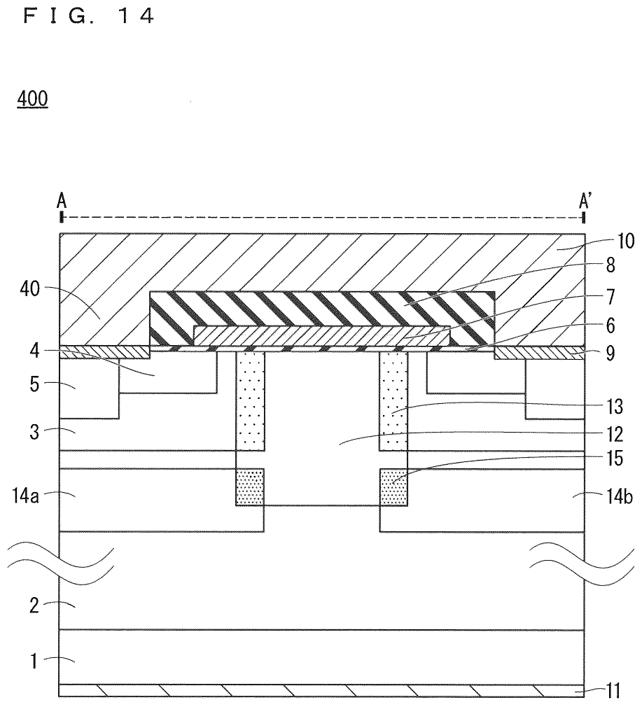

FIG. 14 is a cross-sectional view schematically illustrating a cell structure of a semiconductor device 400 according to a ninth preferred embodiment. The semiconductor device 400 according to the ninth preferred embodiment is another form of the semiconductor device 102 (see FIG. 7) according to the third preferred embodiment, the semiconductor device 103 (see FIG. 9) according to the fourth preferred embodiment, the semiconductor device 201 (see FIG. 11) according to the sixth preferred embodiment, and the semiconductor device 301 (see FIG. 13) according to the eighth preferred embodiment.

As illustrated in FIG. 14, in the semiconductor device 400, a first NW region 12 and second NW regions 14a and 14b overlap each other in the depth direction.

Here, the overlapping of the first NW region 12 and the second NW regions 14a and 14b in the depth direction specifically means that the n-type impurity concentration of an overlapping region 15 where the first NW region 12 and the second NW regions 14a and 14b overlap is substantially equal to or higher than the n-type impurity concentration peaks of the second NW regions 14a and 14b.

Since the first NW region 12 and the second NW regions 14a and 14b overlap in the depth direction, the maximum unipolar current at the time of synchronous rectification can be improved.

In the semiconductor device 400 according to the ninth preferred embodiment, as in the semiconductor device 103 (see FIG. 9) according to the fourth preferred embodiment, the case where the first NW region 12 is provided with the JFET region at the center of the first NW region 12, and the second NW regions 14a and 14b have substantially the same dimensions as a well region 3 has been described, but the present invention is not limited thereto. For example, as in the semiconductor device 102 (see FIG. 7) according to the third preferred embodiment, the second NW regions 14a and 14b do not need to have substantially the same dimension as the well region 3. Additionally, as in the semiconductor device 201 (see FIG. 11) according to the sixth preferred embodiment, the first NW region 12 may be provided with the JFET region and the channel region at the center of the first NW region 12, and the second NW regions 14a and 14b may have substantially the same dimension as the sum of a source region 4 and a well contact region 5. Furthermore, as in the semiconductor device 301 (see FIG. 13) according to the eighth preferred embodiment, the first NW region 12 may be provided with the JFET region, the channel region, and the source region 4 at the center of the first NW region 12, and the second NW regions 14a and 14b may have substantially the same dimension as the well contact region 5.

### Tenth Preferred Embodiment

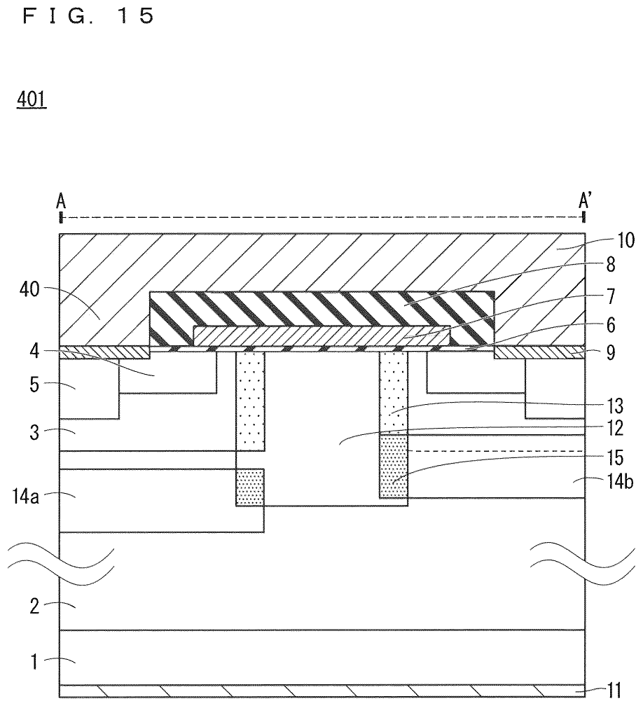

FIG. 15 is a cross-sectional view schematically illustrating a cell structure of a semiconductor device 401 according to a tenth preferred embodiment. The semiconductor device 401 according to the tenth preferred embodiment is another form of the semiconductor device 400 (see FIG. 14) according to the ninth preferred embodiment.

As illustrated in FIG. 15, in the semiconductor device 401, the positions in the depth direction of the impurity concentration peaks of second NW regions 14a and 14b adjacent to each other with a first NW region 12 interposed therebetween are different.

Here, the fact that the positions in the depth direction of the impurity concentration peaks of the second NW regions 14a and 14b adjacent to each other with the first NW region 12 interposed therebetween are different means that the dimensions in the depth direction of overlapping regions 15 of the first NW region 12 and the second NW regions 14a and 14b are different. The n-type impurity concentration of the overlapping region 15 is substantially equal to or higher than the n-type impurity concentration peaks of the second NW regions 14a and 14b.

Since the positions in the depth direction of the impurity concentration peaks of the second NW regions 14a and 14b adjacent to each other with the first NW region 12 interposed therebetween are different, the maximum unipolar current at the time of synchronous rectification can be improved.

In the semiconductor device 401 according to the tenth preferred embodiment, as in the semiconductor device 103 (see FIG. 9) according to the fourth preferred embodiment, the case where the first NW region 12 is provided with the JFET region at the center of the first NW region 12, and the second NW regions 14a and 14b have substantially the same dimensions as a well region 3 has been described, but the present invention is not limited thereto. For example, as in the semiconductor device 102 (see FIG. 7) according to the third preferred embodiment, the second NW regions 14a and 14b do not need to have substantially the same dimension as the well region 3. Additionally, as in the semiconductor device 201 (see FIG. 11) according to the sixth preferred embodiment, the first NW region 12 may be provided with the JFET region and the channel region at the center of the first NW region 12, and the second NW regions 14a and 14b may have substantially the same dimension as the sum of a source region 4 and a well contact region 5. Furthermore, as in the semiconductor device 301 (see FIG. 13) according to the eighth preferred embodiment, the first NW region 12 may be provided with the JFET region, the channel region, and the source region 4 at the center of the first NW region 12, and the second NW regions 14a and 14b may have substantially the same dimension as the well contact region 5.

### Eleventh Preferred Embodiment

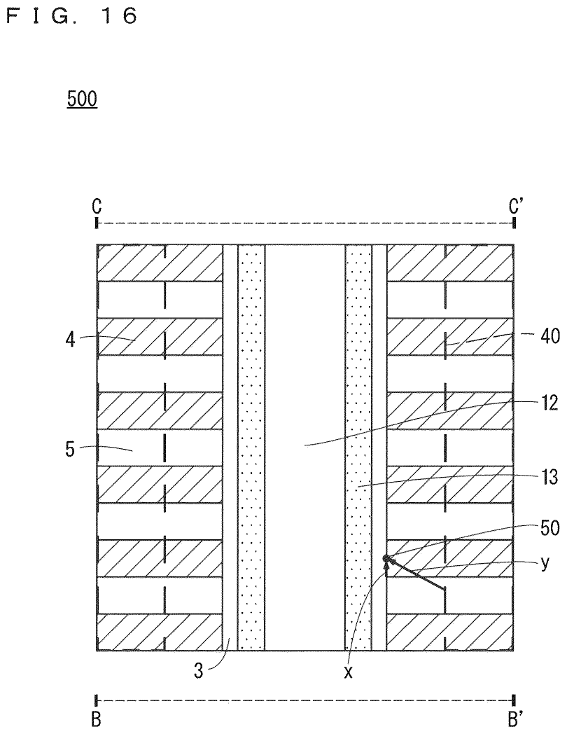

FIG. 16 is a plan view schematically illustrating a cell structure constituting a semiconductor device 500 according to an eleventh preferred embodiment. Specifically, FIG. 16 schematically illustrates a cell structure indicated by B-B′-C′-C illustrated in FIG. 1. Note that in FIG. 16, for convenience of explanation, a gate insulating film 6, a gate electrode 7, an interlayer insulating film 8, an ohmic electrode 9, and a source electrode 10 are omitted.

As illustrated in FIG. 16, in the semiconductor device 500, a source region 4 and a well contact region 5 are alternately provided in substantially the same dimension in a direction orthogonal to a contact region 40. Specifically, the source region 4 and the well contact region 5 extend in a direction orthogonal to the direction in which the contact region 40 extends, and are alternately provided with substantially the same dimension along the direction in which the contact region 40 extends.

A coordinate point 50, which is the position of a well region 3 immediately below the source region 4 most distant from the contact region 40, is a portion where the sheet resistance of the well region 3 is the largest, and is a portion where the voltage rise is the largest. In the semiconductor device 500, by arranging the well contact region 5 with substantially the same dimension as the source region 4, an interval y from a general well contact region 5 to the coordinate point 50 can be shortened to an interval x from the well contact region 5 to the coordinate point 50, so that the sheet resistance of the well region 3 can be reduced. Therefore, it is possible to suppress the rise of the voltage and to suppress deterioration of loss due to malfunction.

### Twelfth Preferred Embodiment

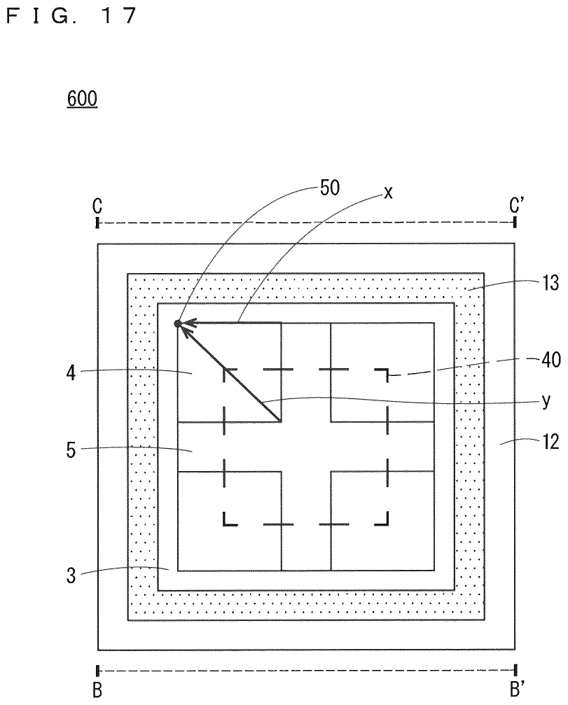

FIG. 17 is a plan view schematically illustrating a cell structure constituting a semiconductor device 600 according to a twelfth preferred embodiment. The semiconductor device 600 according to the twelfth preferred embodiment is another form of the semiconductor device 500 (see FIG. 16) according to the eleventh preferred embodiment.

As illustrated in FIG. 17, in the semiconductor device 600, the cell structure is arranged in a grid pattern, and a well contact region 5 is arranged in a cross pattern.

A coordinate point 50, which is the position of a well region 3 immediately below a source region 4 most distant from a contact region 40, is a portion where the sheet resistance of the well region 3 is the largest, and is a portion where the voltage rise is the largest. In the semiconductor device 600, by arranging the well contact region 5 in a cross shape, an interval y from a general well contact region 5 to the coordinate point 50 can be reduced to an interval x from the well contact region 5 to the coordinate point 50, so that the sheet resistance of the well region 3 can be reduced. Therefore, it is possible to suppress the rise of the voltage and to suppress deterioration of loss due to malfunction.

### Thirteenth Preferred Embodiment

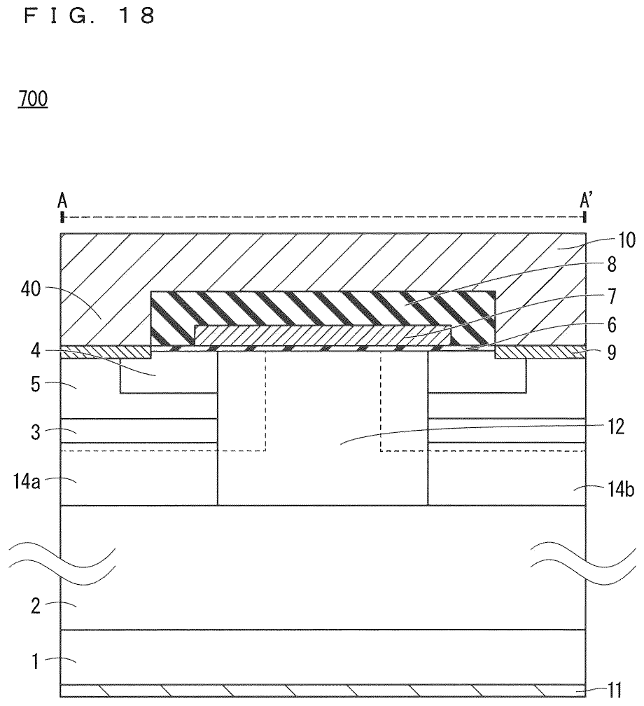

FIG. 18 is a cross-sectional view schematically illustrating a cell structure of a semiconductor device 700 according to a thirteenth preferred embodiment. The semiconductor device 700 according to the thirteenth preferred embodiment is another form of the semiconductor device 100 (see FIG. 2) according to the first preferred embodiment, the semiconductor device 101 (see FIG. 6) according to the second preferred embodiment, the semiconductor device 102 (see FIG. 7) according to the third preferred embodiment, the semiconductor device 103 (see FIG. 9) according to the fourth preferred embodiment, the semiconductor device 200 (see FIG. 10) according to the fifth preferred embodiment, the semiconductor device 201 (see FIG. 11) according to the sixth preferred embodiment, the semiconductor device 300 (see FIG. 12) according to the seventh preferred embodiment, the semiconductor device 301 (see FIG. 13) according to the eighth preferred embodiment, the semiconductor device 400 (see FIG. 14) according to the ninth preferred embodiment, the semiconductor device 401 (see FIG. 15) according to the tenth preferred embodiment, the semiconductor device 500 (see FIG. 16) according to the eleventh preferred embodiment, and the semiconductor device 600 (see FIG. 17) according to the twelfth preferred embodiment.

As illustrated in FIG. 18, in the semiconductor device 700, a well contact region 5 is provided in a well region 3 immediately below a source region 4.

The position of the well region 3 immediately below the source region 4 most distant from a contact region 40 is a portion where the sheet resistance of the well region 3 is the largest, and is a portion where the voltage rise is the largest. In the semiconductor device 700, since the well contact region 5 is provided in the well region 3 immediately below the source region 4, there is a region having a higher p-type impurity concentration than the well region 3, and the sheet resistance of the well region 3 can be reduced. Therefore, it is possible to suppress the rise of the voltage and to suppress deterioration of loss due to malfunction.

### Fourteenth Preferred Embodiment

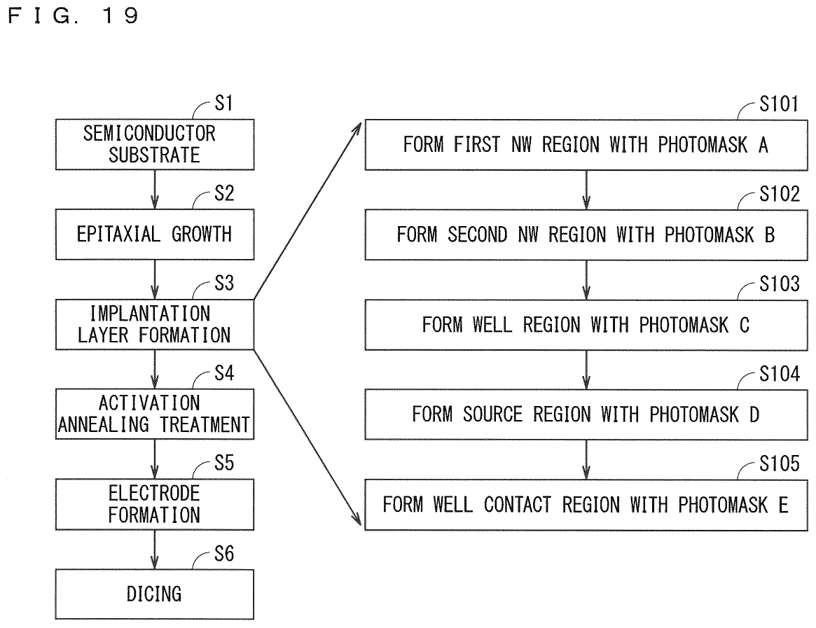

FIG. 19 is a flowchart schematically illustrating a manufacturing process of a semiconductor device according to a fourteenth preferred embodiment. In the fourteenth preferred embodiment, a method of manufacturing the semiconductor device 100 (see FIG. 2) according to the first preferred embodiment, the semiconductor device 101 (see FIG. 6) according to the second preferred embodiment, and the semiconductor device 102 (see FIG. 7) according to the third preferred embodiment will be described.

In step S1, a semiconductor substrate 1 is prepared.

In step S2, n-type silicon carbide is epitaxially grown on the semiconductor substrate 1 to form a drift layer 2.

In step S3, an implantation layer (first NW region 12, second NW regions 14a and 14b, well region 3, source region 4, and well contact region 5) is formed by implanting n-type or p-type impurities from the first main surface side of the drift layer 2. Details of step S3 will be described later.

In step S4, the impurities implanted in step S3 are activated by performing the activation annealing treatment.

In step S5, a gate electrode 7, an ohmic electrode 9, a source electrode 10, and a drain electrode 11 are formed. At this time, a gate insulating film 6 and an interlayer insulating film 8 are also appropriately formed.

In step S6, dicing is performed to complete the semiconductor device.

Next, details of step S3 will be described. Step S3 includes steps S101 to S105.

In step S101, an n-type impurity is implanted from the first main surface side of the drift layer 2 using a photomask A to form the first NW region 12.

In step S102, an n-type impurity is implanted from the first main surface side of the drift layer 2 using a photomask B to form the second NW regions 14a and 14b.

In step S103, a p-type impurity is implanted from the first main surface side of the drift layer 2 using a photomask C to form the well region 3.

In step S104, an n-type impurity is implanted from the first main surface side of the drift layer 2 using a photomask D to form the source region 4.

In step S105, a p-type impurity is implanted from the first main surface side of the drift layer 2 using a photomask E to form the well contact region 5.

Note that the order of steps S101 to S105 is not limited to this.

In the method of manufacturing a semiconductor device according to the fourteenth preferred embodiment, the first NW region 12 is formed using the photomask A, and the second NW regions 14a and 14b are formed using the photomask B different from the photomask used to form the well region 3, the source region 4, and the well contact region 5.

### Fifteenth Preferred Embodiment

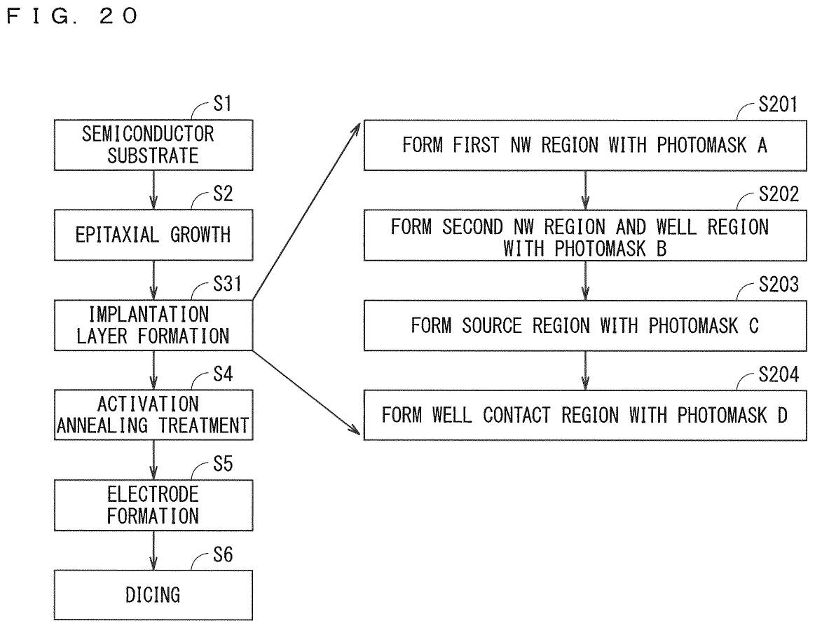

FIG. 20 is a flowchart schematically illustrating a manufacturing process of a semiconductor device according to a fifteenth preferred embodiment. In the fifteenth preferred embodiment, a method of manufacturing the semiconductor device 103 (see FIG. 9) according to the fourth preferred embodiment and the semiconductor device 400 (see FIG. 14) according to the ninth preferred embodiment will be described. Note that steps S1, S2, and S4 to S6 in FIG. 20 are similar to steps S1, S2, and S4 to S6 in FIG. 19, and thus detailed description thereof is omitted here. Hereinafter, steps S201 to S204, which are details of step S31, will be described.

In step S201, an n-type impurity is implanted from the first main surface side of a drift layer 2 using a photomask A to form a first NW region 12.

In step S202, an n-type impurity is implanted from the first main surface side of the drift layer 2 using a photomask B to form second NW regions 14a and 14b. In addition, a p-type impurity is implanted from the first main surface side of the drift layer 2 using the same photomask B to form a well region 3.

In step S203, an n-type impurity is implanted from the first main surface side of the drift layer 2 using a photomask C to form a source region 4.

In step S204, a p-type impurity is implanted from the first main surface side of the drift layer 2 using a photomask D to form a well contact region 5.

Note that the order of steps S201 to S204 is not limited to this.

In the method of manufacturing a semiconductor device according to the fifteenth preferred embodiment, the first NW region 12 is formed using the photomask A, and the second NW regions 14a and 14b are formed using the same photomask B as the well region 3. As compared with the method of manufacturing a semiconductor device according to the fourteenth preferred embodiment, since the second NW regions 14a and 14b are formed using the same photomask B as the well region 3, one step of photolithography can be reduced, and the manufacturing cost of the semiconductor device can be reduced.

### Sixteenth Preferred Embodiment

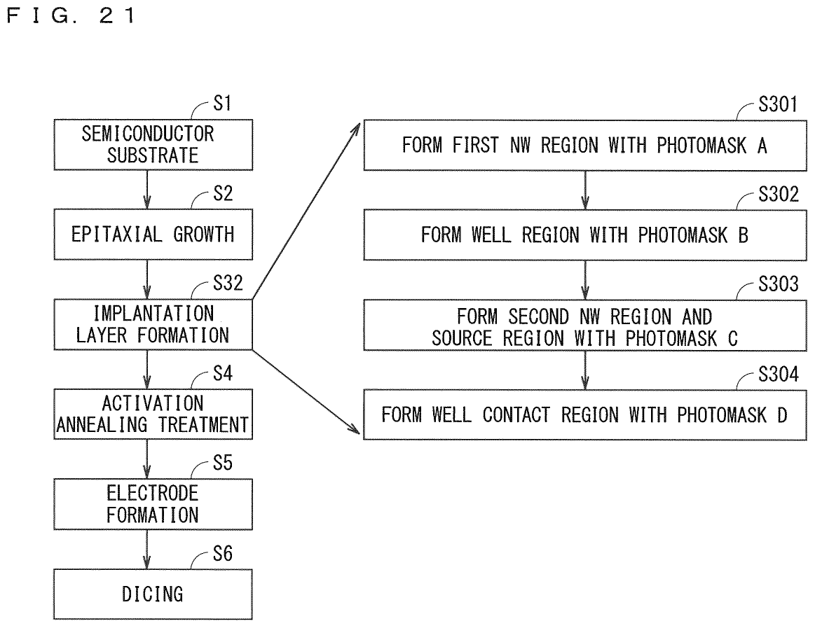

FIG. 21 is a flowchart schematically illustrating a manufacturing process of a semiconductor device according to a sixteenth preferred embodiment. In the sixteenth preferred embodiment, a method of manufacturing the semiconductor device 200 (see FIG. 10) according to the fifth preferred embodiment and the semiconductor device 201 (see FIG. 11) according to the sixth preferred embodiment will be described. Note that steps S1, S2, and S4 to S6 in FIG. 21 are similar to steps S1, S2, and S4 to S6 in FIG. 19, and thus detailed description thereof is omitted here. Hereinafter, steps S301 to S304, which are details of step S32, will be described.

In step S301, an n-type impurity is implanted from the first main surface side of a drift layer 2 using a photomask A to form a first NW region 12.

In step S302, a p-type impurity is implanted from the first main surface side of the drift layer 2 using a photomask B to form a well region 3.

In step S303, an n-type impurity is implanted from the first main surface side of the drift layer 2 using a photomask C to form second NW regions 14a and 14b. In addition, an n-type impurity is implanted from the first main surface side of the drift layer 2 using the same photomask C to form a source region 4.

In step S304, a p-type impurity is implanted from the first main surface side of the drift layer 2 using a photomask D to form a well contact region 5.

Note that the order of steps S301 to S304 is not limited to this.

In the method of manufacturing a semiconductor device according to the sixteenth preferred embodiment, the first NW region 12 is formed using the photomask A, and the second NW regions 14a and 14b are formed using the same photomask C as the source region 4. As compared with the method of manufacturing a semiconductor device according to the fourteenth preferred embodiment, since the second NW regions 14a and 14b are formed using the same photomask C as the source region 4, one step of photolithography can be reduced, and the manufacturing cost of the semiconductor device can be reduced.

### Seventeenth Preferred Embodiment

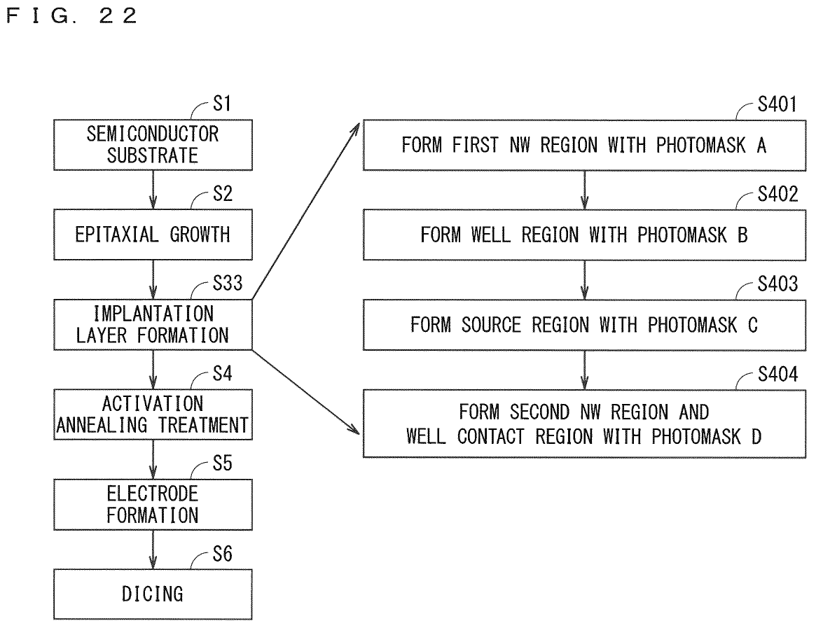

FIG. 22 is a flowchart schematically illustrating a manufacturing process of a semiconductor device according to a seventeenth preferred embodiment. In the seventeenth preferred embodiment, a method of manufacturing the semiconductor device 300 (see FIG. 12) according to the seventh preferred embodiment and the semiconductor device 301 (see FIG. 13) according to the eighth preferred embodiment will be described. Note that steps S1, S2, and S4 to S6 in FIG. 22 are similar to steps S1, S2, and S4 to S6 in FIG. 19, and thus detailed description thereof is omitted here. Hereinafter, steps S401 to S404, which are details of step S33, will be described.

In step S401, an n-type impurity is implanted from the first main surface side of a drift layer 2 using a photomask A to form a first NW region 12.

In step S402, a p-type impurity is implanted from the first main surface side of the drift layer 2 using a photomask B to form a well region 3.

In step S403, an n-type impurity is implanted from the first main surface side of the drift layer 2 using a photomask C to form a source region 4.

In step 404, an n-type impurity is implanted from the first main surface side of the drift layer 2 using a photomask D to form second NW regions 14a and 14b. In addition, a p-type impurity is implanted from the first main surface side of the drift layer 2 using the same photomask D to form a well contact region 5.

Note that the order of steps S401 to S404 is not limited to this.

In the method of manufacturing a semiconductor device according to the seventeenth preferred embodiment, the first NW region 12 is formed using the photomask A, and the second NW regions 14a and 14b are formed using the same photomask D as the well contact region 5. As compared with the method of manufacturing a semiconductor device according to the fourteenth preferred embodiment, since the second NW regions 14a and 14b are formed using the same photomask D as the well contact region 5, one step of photolithography can be reduced, and the manufacturing cost of the semiconductor device can be reduced.

Note that within the scope of the present disclosure, preferred embodiments can be freely combined, and each preferred embodiment can be appropriately modified or omitted.

### APPENDIX

Hereinafter, various aspects of the present disclosure will be collectively described as appendices.

### Appendix 1

A semiconductor device comprising:
a drift layer of a first conductivity type including a first main surface and a second main surface facing the first main surface;
a plurality of first impurity regions of a second conductivity type provided on the first main surface side of the drift layer;
a junction field effect transistor (JFET) region provided between the first impurity regions;
a second impurity region of the first conductivity type provided so as to overlap a part of each of the first impurity regions in the JFET region; and
a plurality of third impurity regions of the first conductivity type having an impurity concentration peak at a position deeper than an impurity concentration peak of the first impurity region in at least a part of each of the first impurity regions in a depth direction connecting the first main surface and the second main surface.

### Appendix 2

The semiconductor device according to appendix 1, wherein
the second impurity region and the third impurity region are connected, and
an impurity concentration peak of the third impurity region is the same as an impurity concentration of the second impurity region at the same depth as an impurity concentration peak of the third impurity region.

### Appendix 3

The semiconductor device according to appendix 1, further comprising an overlapping region where the second impurity region and the third impurity region overlap each other, wherein
an impurity concentration of the overlapping region is higher than an impurity concentration of each of the second impurity region and the third impurity region at the same depth.

### Appendix 4

The semiconductor device according to appendix 3, wherein a dimension of the third impurity region is the same as a dimension of the first impurity region in a horizontal direction orthogonal to the depth direction.

### Appendix 5

The semiconductor device according to appendix 2, wherein
the second impurity region is also provided in a channel region that is a region between the JFET region and the fourth impurity region of the first conductivity type, and
in a horizontal direction orthogonal to the depth direction, a dimension of the third impurity region is the same as a dimension of the fourth impurity region, or is the same as a sum of a dimension of the fourth impurity region and a dimension of a fifth impurity region of the second conductivity type adjacent to the fourth impurity region.

### Appendix 6

The semiconductor device according to appendix 3, wherein
the second impurity region is also provided in a channel region that is a region between the JFET region and the fourth impurity region of the first conductivity type, and
in a horizontal direction orthogonal to the depth direction, a dimension of the third impurity region is the same as a dimension of the fourth impurity region, or is the same as a sum of a dimension of the fourth impurity region and a dimension of a fifth impurity region of the second conductivity type adjacent to the fourth impurity region.

### Appendix 7

The semiconductor device according to appendix 2, wherein
the second impurity region is provided in a region other than a fifth impurity region of the second conductivity type, and
in a horizontal direction orthogonal to the depth direction, a dimension of the third impurity region is the same as a dimension of the fifth impurity region.

### Appendix 8

The semiconductor device according to appendix 3, wherein
the second impurity region is provided in a region including a part of the fifth impurity region of the second conductivity type, and
in a horizontal direction orthogonal to the depth direction, a dimension of the third impurity region is the same as a dimension of the fifth impurity region.

### Appendix 9

The semiconductor device according to any one of appendices 4, 6, or 8, wherein
the second impurity region and the third impurity region overlap each other in the depth direction, and
an impurity concentration of the overlapping region is the same as an impurity concentration peak of the third impurity region.

### Appendix 10

The semiconductor device according to appendix 9, wherein positions in the depth direction of impurity concentration peaks of the third impurity regions adjacent to each other with the second impurity region interposed therebetween are different.

### Appendix 11

The semiconductor device according to any one of appendices 1 to 10, wherein on the first main surface in plan view, the fourth impurity region of the first conductivity type and the fifth impurity region of the second conductivity type extend in a direction orthogonal to a direction in which a contact region extends, and are alternately provided with the same dimension along the direction in which the contact region extends.

### Appendix 12

The semiconductor device according to any one of appendices 1 to 10, wherein on the first main surface in plan view, a cell structure constituting the semiconductor device is arranged in a grid pattern, and a fifth impurity region of the second conductivity type is arranged in a cross pattern.

### Appendix 13

The semiconductor device according to any one of appendices 1 to 12, wherein the fifth impurity region of the second conductivity type is provided immediately below the fourth impurity region of the first conductivity type in the depth direction.

### Appendix 14

The semiconductor device according to any one of appendices 1 to 13, wherein the second impurity region has an impurity concentration that is depleted at a maximum rated voltage at a lowermost portion in the depth direction.

### Appendix 15

The semiconductor device according to any one of appendices 1 to 14, wherein the third impurity region has an impurity concentration that is depleted at a maximum rated voltage.

### Appendix 16

A method of manufacturing the semiconductor device according to any one of appendices 1 to 3, wherein
the second impurity region is formed using a photomask for forming the second impurity region, and
the third impurity region is formed using a photomask for forming the third impurity region.

### Appendix 17

A method of manufacturing the semiconductor device according to appendix 4 or 9, wherein
the second impurity region is formed using a photomask for forming the second impurity region, and
the third impurity region is formed using a photomask for forming the first impurity region.

### Appendix 18

A method of manufacturing the semiconductor device according to appendix 5 or 6, wherein
the second impurity region is formed using a photomask for forming the second impurity region, and
the third impurity region is formed using a photomask for forming the fourth impurity region.

### Appendix 19

A method of manufacturing the semiconductor device according to appendix 7 or 8, wherein
the second impurity region is formed using a photomask for forming the second impurity region, and
the third impurity region is formed using a photomask for forming the fifth impurity region.

While the disclosure has been shown and described in detail, the foregoing description is in all aspects illustrative and not restrictive. It is therefore understood that numerous modifications and variations can be devised.

What is claimed is:

1. A semiconductor device comprising:
a drift layer of a first conductivity type including a first main surface and a second main surface facing the first main surface;
a plurality of first impurity regions of a second conductivity type provided on the first main surface side of the drift layer;
a junction field effect transistor (JFET) region provided between the first impurity regions;
a second impurity region of the first conductivity type provided so as to overlap a part of each of the first impurity regions in the JFET region; and
a plurality of third impurity regions of the first conductivity type having an impurity concentration peak at a position deeper than an impurity concentration peak of the first impurity region in at least a part of each of the first impurity regions in a depth direction connecting the first main surface and the second main surface.

2. The semiconductor device according to claim 1, wherein
the second impurity region and the third impurity region are connected, and
an impurity concentration peak of the third impurity region is the same as an impurity concentration of the second impurity region at the same depth as an impurity concentration peak of the third impurity region.

3. The semiconductor device according to claim 1, further comprising an overlapping region where the second impurity region and the third impurity region overlap each other, wherein
an impurity concentration of the overlapping region is higher than an impurity concentration of each of the second impurity region and the third impurity region at the same depth.

4. The semiconductor device according to claim 3, wherein a dimension of the third impurity region is the same as a dimension of the first impurity region in a horizontal direction orthogonal to the depth direction.

5. The semiconductor device according to claim 2, wherein
the second impurity region is also provided in a channel region that is a region between the JFET region and the fourth impurity region of the first conductivity type, and
in a horizontal direction orthogonal to the depth direction, a dimension of the third impurity region is the same as a dimension of the fourth impurity region, or is the same as a sum of a dimension of the fourth impurity region and a dimension of a fifth impurity region of the second conductivity type adjacent to the fourth impurity region.

6. The semiconductor device according to claim 3, wherein
the second impurity region is also provided in a channel region that is a region between the JFET region and the fourth impurity region of the first conductivity type, and
in a horizontal direction orthogonal to the depth direction, a dimension of the third impurity region is the same as a dimension of the fourth impurity region, or is the same as a sum of a dimension of the fourth impurity region and a dimension of a fifth impurity region of the second conductivity type adjacent to the fourth impurity region.

7. The semiconductor device according to claim 2, wherein
the second impurity region is provided in a region other than a fifth impurity region of the second conductivity type, and
in a horizontal direction orthogonal to the depth direction, a dimension of the third impurity region is the same as a dimension of the fifth impurity region.

8. The semiconductor device according to claim 3, wherein
the second impurity region is provided in a region including a part of a fifth impurity region of the second conductivity type, and
in a horizontal direction orthogonal to the depth direction, a dimension of the third impurity region is the same as a dimension of the fifth impurity region.

9. The semiconductor device according to claim 3, wherein
the second impurity region and the third impurity region overlap each other in the depth direction, and
an impurity concentration of the overlapping region is the same as an impurity concentration peak of the third impurity region.

10. The semiconductor device according to claim 9, wherein positions in the depth direction of impurity concentration peaks of the third impurity regions adjacent to each other with the second impurity region interposed therebetween are different.

11. The semiconductor device according to claim 1, wherein on the first main surface in plan view, the fourth impurity region of the first conductivity type and the fifth impurity region of the second conductivity type extend in a direction orthogonal to a direction in which a contact region extends, and are alternately provided with the same dimension along the direction in which the contact region extends.

12. The semiconductor device according to claim 1, wherein on the first main surface in plan view, a cell structure constituting the semiconductor device is arranged in a grid pattern, and a fifth impurity region of the second conductivity type is arranged in a cross pattern.

13. The semiconductor device according to claim 1, wherein the fifth impurity region of the second conductivity type is provided immediately below the fourth impurity region of the first conductivity type in the depth direction.

14. The semiconductor device according to claim 1, wherein the second impurity region has an impurity concentration that is depleted at a maximum rated voltage at a lowermost portion in the depth direction.

15. The semiconductor device according to claim 1, wherein the third impurity region has an impurity concentration that is depleted at a maximum rated voltage.

16. A method of manufacturing the semiconductor device according to claim 1, wherein
the second impurity region is formed using a photomask for forming the second impurity region, and
the third impurity region is formed using a photomask for forming the third impurity region.

17. A method of manufacturing the semiconductor device according to claim 4, wherein
the second impurity region is formed using a photomask for forming the second impurity region, and
the third impurity region is formed using a photomask for forming the first impurity region.

18. A method of manufacturing the semiconductor device according to claim 5, wherein
the second impurity region is formed using a photomask for forming the second impurity region, and
the third impurity region is formed using a photomask for forming the fourth impurity region.

19. A method of manufacturing the semiconductor device according to claim 7, wherein
the second impurity region is formed using a photomask for forming the second impurity region, and
the third impurity region is formed using a photomask for forming the fifth impurity region.
